(19) United States
(12) Patent Application Publication
(10) Pub. No.: US 2010/0090739 A1
(43) Pub. Date: Apr. 15, 2010

(54) Method and Apparatus for Removing Narrow Pulses from a Clock Waveform

(75) Inventor: Shuo Huang, Novato, CA (US)

Correspondence Address: James M. Wu;JW Law Group, 84 W. Santa Clara Street, Suite 820, San Jose, CA, 95113, US

(73) Assignee: Tellabs Petaluma, Inc., Naperville, IL (US)

(21) Appl. No.: 12/252,118

(22) Filed: Oct. 15, 2008

(51) Int. Cl. H03K 3/017

(52) U.S. Cl. 327/176; 327/172

(57) ABSTRACT

A method and a device for controlling and removing narrow pulses in a clock waveform using a delay function are disclosed. A circuit device includes three circuits wherein the first circuit is capable of generating an edge trigger signal in response to a waveform of an input signal and a waveform of an output signal. While the second circuit facilitates removing a narrow pulse from the waveform of the input signal, the third circuit is capable of generating a delayed output waveform having pulses greater than a predefined minimal pulse width. In one embodiment, the first, second, and third circuits are an exclusive OR gate, a delay circuit, and a D flip-flop, respectively.

### FIELD

The exemplary embodiment(s) of the present invention relates to digital processing and communication systems. More specifically, the exemplary embodiment(s) of the present invention relates to clock signal management.

### BACKGROUND

In a conventional communication system, various functional circuits in the system are synchronized by a clock or system clock. Circuits typically behave normally and perform assigned functions accurately as long as the system clock provides accurate clock waveforms. The circuits, however, will not function properly when the system clock fails or provides inaccurate clock waveforms. For example, incorrect data or control signals can be generated when the clock waveform contains glitches such as narrow pulses. Glitches can occur in response to various external as well as internal factors such as noise, environment, and device failures.

To enhance reliability of a system clock, a redundant clock source is often built as a backup clock source for the system. For example, when a main system clock source fails, the redundant backup clock source will automatically be activated to take over the responsibility of providing a system clock from the main system clock source. The process of changing from one clock waveform to another clock waveform is also known as a “switch-over” scenario.

During a switch-over from a clock source to another clock source, one or more narrow pulses or glitches can be introduced. Such glitches or narrow pulses can cause problems to the circuits in the system. For example, a narrow pulse or a glitch can cause a state machine to generate an unexpected state due to inadequate setup or hold time to the circuit.

### SUMMARY

Embodiment(s) of the present invention includes a circuit capable of removing narrow pulses and method for implementing the same. A device includes a first, second, and third circuits wherein the first circuit is capable of generating an edge trigger signal in response to an input signal and an output signal. While the second circuit facilitates removing a narrow pulse from the input signal, the third circuit is capable of generating a delayed output signal having pulses with a greater than a predefined minimal pulse width. In one embodiment, the first, second, and third circuits are an exclusive OR gate, a delay line, and a D flip-flop, respectively.

Additional features and benefits of the exemplary embodiment(s) of the present invention will become apparent from the detailed description, figures and claims set forth below.

### BRIEF DESCRIPTION OF THE DRAWINGS

The exemplary embodiment(s) of the present invention will be understood more fully from the detailed description given below and from the accompanying drawings of various embodiments of the invention, which, however, should not be taken to limit the invention to the specific embodiments, but are for explanation and understanding only.

FIG. 1 is a block diagram illustrating a device capable of blocking narrow pulses in accordance with one embodiment of the present invention;

FIG. 2 is a block diagram illustrating a device capable of blocking narrow pulses using a delay element in accordance with one embodiment of the present invention;

FIG. 3 is a timing diagram illustrating a process of removing or blocking narrow pulses or glitches in accordance with one embodiment of the present invention; and

FIG. 4 is a flowchart illustrating a process of filtering narrow pulses in accordance with one embodiment of the present invention.

### DETAILED DESCRIPTION

Exemplary embodiment(s) of the present invention is described herein in the context of a method, system and apparatus of removing narrow pulses in an input waveform via a delay element.

Those of ordinary skills in the art will realize that the following detailed description of the exemplary embodiment(s) is illustrative only and is not intended to be in any way limiting. Other embodiments will readily suggest themselves to such skilled persons having the benefit of this disclosure. Reference will now be made in detail to implementations of the exemplary embodiment(s) as illustrated in the accompanying drawings. The same reference indicators will be used throughout the drawings and the following detailed description to refer to the same or like parts.

In the interest of clarity, not all of the routine features of the implementations described herein are shown and described. It will, of course, be understood that in the development of any such actual implementation, numerous implementation-specific decisions must be made in order to achieve the developer's specific goals, such as compliance with application- and business-related constraints, and that these specific goals will vary from one implementation to another and from one developer to another. Moreover, it will be understood that such a development effort might be complex and time-consuming, but would nevertheless be a routine undertaking of engineering for those of ordinary skills in the art having the benefit of this disclosure.

It should be noted that those of ordinary skills in the art will recognize that devices of any form of digital circuits, such as hardwired devices, programmable logic device (“PLD”), field programmable gate arrays (“FPGAs”), application specific integrated circuits (“ASICs”), or the like, may also be used without departing from the scope and spirit of the inventive concepts disclosed herein. In addition, the components, process steps, and/or data structures described herein may be implemented using various types of operating systems, computing platforms, computer programs, and/or general purpose machines.

A device capable of removing narrow pulses or glitches from a clock waveform using a delay function is disclosed. The circuit device includes an exclusive OR (“XOR”) gate, a D flip-flop, and a delay element. The XOR gate, in one embodiment, is capable of generating an edge trigger signal in response to an input clock signal and an output clock signal. The delay element provides an output of the same waveform as seen as at input with a predetermined latency. Glitches can cause a device to malfunction when a clock pulse is too narrow or the time between two clock edges is too short. A pulse shorter than the predefined minimum pulse width is a glitch or narrow pulse. The term “glitch” and “narrow pulse” are used interchangeably thereinafter. In addition, the term “removing glitches,” “filtering glitches,” “blocking glitches,” “minimizing glitches,” and the like can be used interchangeably hereinafter.

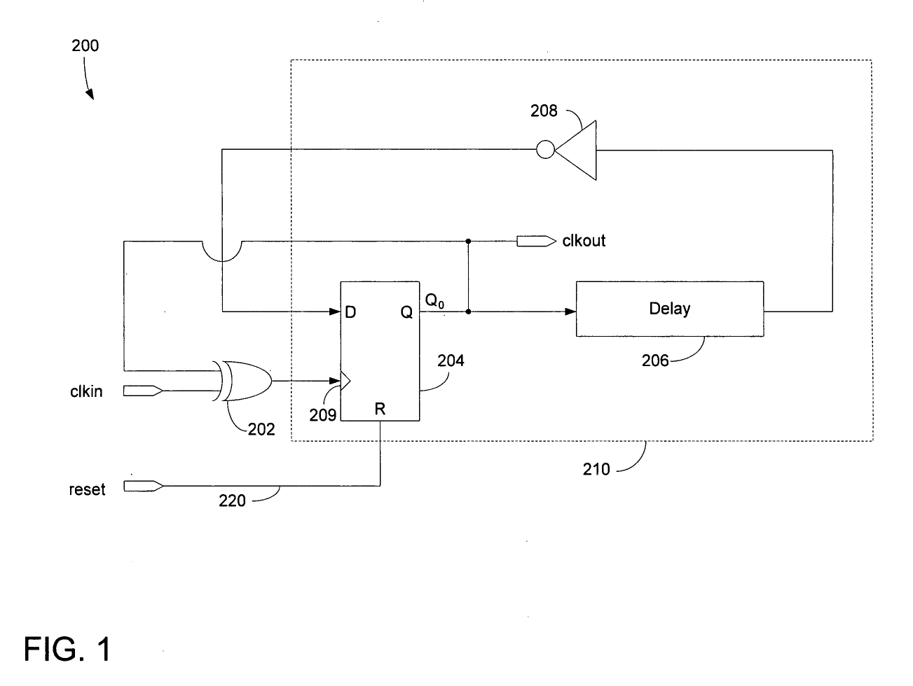

FIG. 1 is a block diagram 200 illustrating a device capable of blocking narrow pulses using a delay element in accordance with one embodiment of the present invention. Diagram 200 includes an XOR gate 202 and a glitch filter 210, wherein filter 210 includes a D flip-flop 204 and a delay element 206. The output of delay element 206 is fed to the D input of D flip-flop 204 via an inverter 208. It should be noted that the underlying concept of the exemplary embodiment(s) of the present invention would not change if one or more blocks (circuit) were added to or removed from diagram 200.

XOR gate 202 provides a logic “1” value when its inputs have different logic values. In one embodiment, XOR gate 202 generates an edge trigger signal for D flip-flop 204 in response to the logic values of clock input (“clkin”) and clock output (“clkout”). Clkin is an input clock signal that may have glitches. Clkout is generated by D flip-flop 204 and contains a waveform. It should be noted that XOR gate 202 can be replaced with any other types of logic circuits as long as they perform similar functions as an XOR function.

D flip-flop 204 includes a clock input 209, a data input D (“D input”), a Q output Q₀, and an R reset. While clock input 209 receives the edge trigger signal from XOR 202, the D input is fed by an inverted waveform of a delayed output clock signal. Q₀ is clkout and D flip-flop 204 can be reset by a reset signal of reset via connection 220. D flip-flop 204 takes or latches in a logic state or value from the D input at the time of a rising edge of the edge trigger signal at input 209. Alternatively, D flip-flop 204 can also be replaced by a falling edge triggered D flip-flop. And XOR 202 can be replaced by a XNOR gate. The resultant circuit would work the same. To simplify the circuit description, the following description only addresses circuit using the rising edge triggered D flip-flop 204 and XOR gate 202. It should be understood that embodiment(s) of the present invention can apply to either circuit with falling edge triggered or the rising edge triggered flip-flop. The value of D flip-flop 204 does not change during any other time except at the time of rising edges of the edge trigger signal. D flip-flop can also be viewed as sequential delay logic or a register since it is capable of delaying or storing the input value for a clock cycle.

Delay element 206 receives signals from the Q₀ output and outputs a delayed output waveform and is capable of delaying a signal for a predefined delay. Inverter 208 receives the delayed output waveform from delay element 206 and generates an inverted waveform of the delayed output clock signal. The inverted waveform of the output signal is subsequently latched by D flip-flop 204 at the rising edge of the edge trigger signal. It should be noted that inverter 208 can be placed or located at a place anywhere between the Q₀ out and the D input of D flip-flop 204.

During operation, the device blocks narrow pulses on a clock signal or clkin with predetermined minimum allowed pulse width. In one embodiment, the device passes all pulses of waveform of the input signal having the pulse width greater than a predefined minimum pulse width. The device, however, blocks pulses that are narrower than certain width. In a normal operation mode, when the source clock signal does not have any glitches, the output clock has a small and fixed delay from the input clock. Unlike a typical digital phase-locked loop (“PLL”) which may be used to regenerate a clock, the embodiment(s) of the present invention minimizes added jitters. It should be noted that the device can be implemented in any programmable logic device such as FPGA and programmable logic device (“PLD”). Alternatively, the device can also be made or fabricated in custom circuit chips such as ASIC.

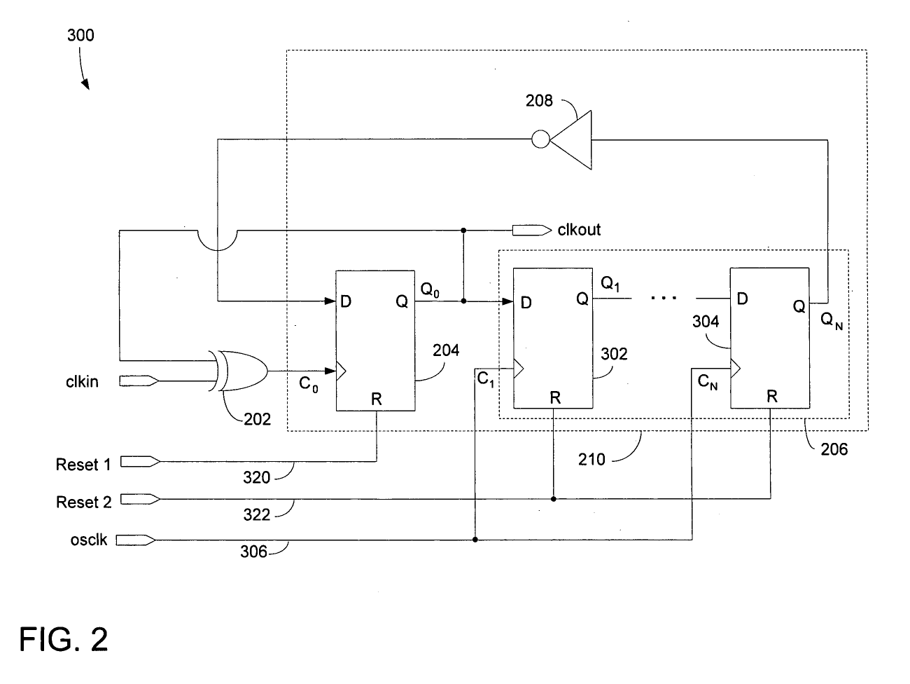

FIG. 2 is a block diagram 300 illustrating a device capable of blocking narrow pulses using a delay element in accordance with one embodiment of the present invention. Similar to diagram 200 in FIG. 1, diagram 300 includes an XOR gate 202 and a glitch filter 210, wherein filter 210 includes a D flip-flop 204 and a delay element 206. The output of delay element 206 is fed to the D input of D flip-flop 204 via an inverter 208. Inverter 208 can be situated at a place anywhere between the Q₀ out and the D input of D flip-flop 204. D flip-flop 204 can be reset by a reset signal of reset 1 via connection 320. It should be noted that the underlying concept of the exemplary embodiment(s) of the present invention would not change if one or more blocks (circuit) were added to, relocated, or removed from diagram 300.

Delay element 206, in one embodiment, includes a series of D flip-flops 302-304, wherein D flip-flops 302-304 can include up to N numbers of D flip-flops. Delay element 206 can be reset by reset 2 via connection 322. Delay element 206 is configured to perform a delay function in accordance with a predefined minimum allowed pulse width. Similar to D flip-flop 204, D flip-flops 302-304 include D inputs, Q outputs Q₁-Q_{N}, clock inputs C₁-C_{N}, and R resets and they are connected in a series synchronized by a local oscillated clock (“osclk”). Depending on the applications, a delay time can be determined in accordance with the minimum allowed pulse width. For example, the number of D flip-flops employed in delay element 206 is structured thereby the delay fulfills the requirement of the minimum pulse width. It should be noted that delay element 206 can be implemented by any logic components other than D flip-flops as long as it is capable of performing a delay function.

In one operation, clkin is a system clock signal and its waveform may contain glitches or narrow pulses during a process of switch-over. Clkout is the clock signal output which does not contain narrow pulses or glitches. In other words, clkout is a regenerated clkin without glitches or narrow pulses. To synchronize D flip-flops 302-304 in delay element 206, osclk, a local oscillated clock, is used. In one aspect, osclk is continuously available and is not affected by error conditions such as glitches occurred in clkin. In one embodiment, osclk is clocked at a higher frequency than that of clkin.

Referring back to FIG. 2, the device, in one embodiment, includes N+1 D-type flip-flops wherein D flip-flops are also known as registers or bit-storage devices since they can store data between clock signals. N+1 D flip-flops 204 and 302-304 are connected in a cascade configuration and they are numbered from 0 to N, wherein N can be any predetermined integer number. D flip-flop 204 or register 0 is clocked by clock signal C₀ or the edge trigger signal from XOR 202 whereas D flip-flops 302-304 or registers 1 through N are clocked by osclk. The number N is selected whereby N plus one (N+1) multiplying a period of osclk is less than half a cycle of clkin. In addition, N multiplying a period of osclk is greater than a maximum pulse width that the device is configured to block.

During an operation, when a rising edge of clkin arrives and clkout (Q₀) has a logic value “0”, XOR gate 202 outputs an edge trigger signal having logic value “1” which is used as C₀ to clock register 0. Logic value “1” indicates an active logic state whereas logic value “0” indicates an inactive logic state. If Q_{N} has logic value “0”, the D input of register 0 has logic value “1”. When the rising edge of edge trigger signal arrives at the clock input (C₀) of D flip-flop register 0, the register 0 latches in the logic state from the D input, and changes its logic state to logic value “1”. When output Q₀ turns to logic value “1”, it is subsequently sampled by register 1 or D flip-flop 302 at the next rising edge of osclk. When output Q₁ turns to logic value “1”, it is further sampled by register 2, not shown in FIG. 2, at the next rising edge of osclk, and so on. As such, a signal such as clkout can be delayed by a set of cascaded registers (register 1 through register N). Before Q_{N} changes its logic state, any edge at signal C₀ would not change the value at Q₀. After Q_{N} turns to logic “1”, register 0 can again be toggled.

When clkin changes from logic value “1” to “0” and clkout Q₀ stays at logic value “1”, XOR gate 202 outputs a pulse of the edge trigger signal. When the rising edge of the edge trigger signal or C₀ reaches to register 0, it clocks in the D input value. Since Q_{N} has logic value “1”, the D input of register 0 is logic value “0”. After latching in the D input of register 0, output Q₀ turns from logic value “1” to logic value “0”. The logic value “0” at Q₀ is subsequently sampled by register 1 at the next rising edge of osclk. As such, the logic value “0” at Q₀ propagates through the cascaded registers from register 1 through register N to provide configured delay time.

The following timing diagram illustrates a detailed description of glitch removing implementation operated by the device illustrated FIG. 2.

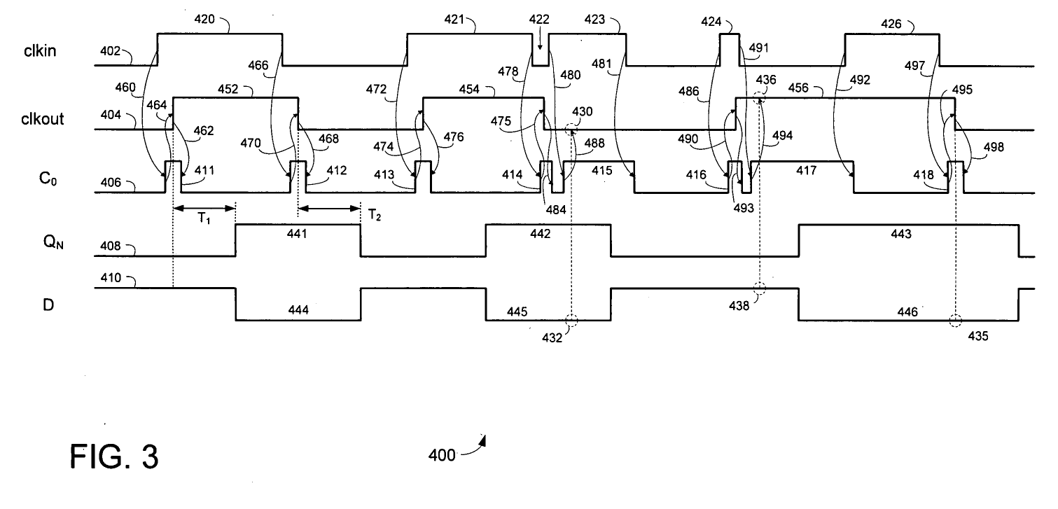

FIG. 3 is a timing diagram 400 illustrating a process of removing or blocking narrow pulses or glitches in accordance with one embodiment of the present invention. Timing diagram 400 includes timing diagram or waveforms of clkin 402, clkout 404, C₀ 406, Q_{N} 408, and D input 410. Clkin 402 is a waveform having multiple pulses 420-426 and clkout 404 includes pulses 452-456. Similarly, C₀ 406 includes pulses 411-418 and Q_{N} 408 includes pulses 441-443. As illustrated in FIG. 2, clkout is the same waveform of Q₀

When pulse 420 of clkin arrives, rising edge 460 triggers pulse 411 of C₀. Rising edge 464 of C₀ subsequently triggers pulse 452 of clkout since D input 410 has a logic value “1”. Rising edge 462 of pulse 452 triggers falling edge of pulse 411 of C₀. After a predefined time delay T₁, Q_{N} generates a pulse 441 by changing its waveform from logic value “0” to logic value “1”. Falling edge 466 of pulse 420 of clkin triggers pulse 412 of C₀ and rising edge 470 of pulse 412 of C₀ subsequently triggers falling edge of pulse 452 of clkout. Falling edge 468 of pulse 452 of clkout triggers falling edge of pulse 412 of C₀. After a predefined time delay T₂, Q_{N} changes its waveform from logic value “1” to logic value “0”.

Upon arriving of pulse 421, rising edge 472 of pulse 421 of clkin triggers pulse 413. Since D input 410 has a logic value “1” at rising edge 474 of pulse 413 of C₀, pulse 454 of clkout is produced or regenerated. Rising edge 476 of pulse 454 triggers falling edge of pulse 413 of C₀. After a predefined time delay, Q_{N} outputs pulse 442. Falling edge 478 of pulse 421 triggers pulse 414 of C₀ and rising edge 475 of pulse 414 of C₀ subsequently triggers falling edge of pulse 454 of clkout. When a negative narrow pulse 422 occurs, rising edge 480 of pulse 423 triggers pulse 415 of C₀. After rising edge 488 of pulse 415 of C₀ tries to latch logic value of D input 410 at timing points 430-432, waveform of clkout does not change its logic state since logic value of clkout at timing point 430 is the same logic value of D input 410 at timing point 432. Falling edge 481 of pulse 423 of clkin triggers falling edge of pulse 415 of C₀. After a predefined time delay, Q_{N} changes from logic value “1” to logic value “0”.

After arrival of pulse 424 of clkin, rising edge 486 of pulse 424 triggers pulse 416 of C₀. Pulse 424 is narrow which is a glitch or a narrow pulse. Since D input 410 maintains a logic value “1” at the time of rising edge 490 of pulse 416 of C₀, pulse 456 of clkout is generated. Rising edge 493 of pulse 456 subsequently triggers falling edge of pulse 416 of C₀. After a predefined time delay, Q_{N} generates a pulse 443. When falling edge 491 of positive narrow pulse 424 initiates pulse 417 of C₀, rising edge 494 of pulse 417 of C₀ tries to latch logic value of D input 410 at timing points 436-438. Pulse 456 of clkout does not change its logic state since D input 410 has a logic value “1” at timing point 438.

Rising edge 492 of pulse 426 of clkin triggers falling edge of pulse 417 of C₀. Falling edge of C₀ has no effect on D flip-flop since it is configured to be triggered on rising edge of C₀. As such, pulse 456 maintains its logic state. Falling edge 497 of pulse 426 of clkin triggers pulse 418 of C₀ and rising edge 495 of pulse 418 of C₀ subsequently triggers falling edge of pulse 456 of clkout in accordance with the logic value of D input at timing point 435. Falling edge 498 of pulse 456 of clkout triggers falling edge of pulse 418 of C₀. After a predefined time delay, Q_{N} changes from logic value “1” to logic value “0”.

As can be seen, both negative narrow pulse 422 and positive narrow pulse 424 occurred in the clkin waveform have been removed from the clkout waveform. For removing narrow pulse 424, the circuit missed the rising edge of pulse 426. The output clock, however, resumes its normal clock output as soon as the input clock is back to normal pulse width (i.e., no narrow pulses). An advantage of using a narrow pulse blocking circuit is to avoid timing violations (such as setup and/or hold timing violations) due to narrow clock pulses.

For the device to work, N needs to equal two (2) or more D flip-flops to achieve a controllable minimum delay. Also, osclk is configured to be a faster clock than clkin. For example, three (3) osclk cycles should be smaller than one pulse width of clkin. In other words, if the duty cycle of clkin is 50%, the frequency of osclk should be more than six (6) times of frequency of clkin for the device to operate. It should be noted that other types of delay circuits may be used to achieve similar functions without above mentioned limitations on osclk.

The exemplary embodiment(s) of the present invention includes various processing steps, which will be described below. The steps of the embodiment(s) may be embodied in circuit, machine, or computer executable instructions. The steps of the embodiment(s) may be performed by specific hardware components that contain hard-wired logic for performing the steps, or by any combination of programmed computer components and custom hardware components.

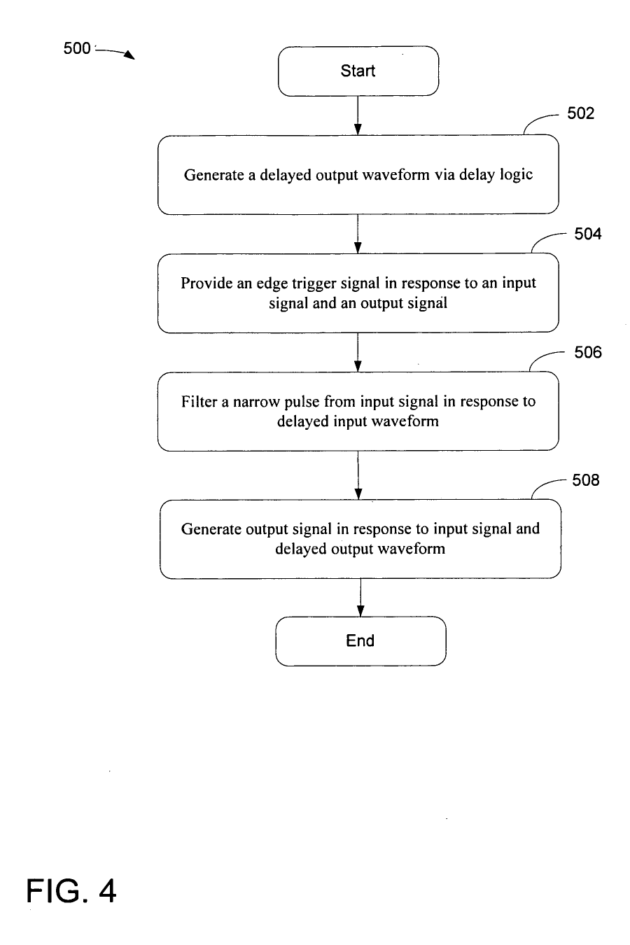

FIG. 4 is a flowchart illustrating a process of filtering narrow pulses in accordance with one embodiment of the present invention. At block 502, a process for filtering narrow pulses generates a delayed output clock via delay logic for a predetermined delay. For example, the process is capable of identifying a delay time that is greater than a predefined minimum allowed pulse width and less than half of a period of the input clock. In addition, the process is capable of identifying a delay time that equals to a predefined minimum allowed pulse width and less than half of a period of the input signal.

At block 504, the process provides an edge trigger signal in response to an input clock and an output clock. The process, in one embodiment, is capable of feeding the input clock and the output clock to an exclusive OR gate to produce the edge trigger signal.

At block 506, the process filters a narrow pulse or glitch from the input clock in response to the delayed output clock signal. For example, the process is capable of removing glitches from a waveform of the input clock signal utilizing D flip-flops and a delay element capable of delaying a signal for specific time duration.

At block 508, the process generates an output signal in response to the input signal and the waveform. For example, the process is capable of providing a delayed output signal with a narrow pulse removed. In one embodiment, the process is configured to provide the output signal via a D flip-flop configured to receive the edge trigger signal for clocking the D flip-flop. In addition, the output signal via a D flip-flop is capable of receiving an inverted and delayed output waveform as data input.

While particular embodiments of the present invention have been shown and described, it will be obvious to those skilled in the art that, based upon the teachings herein, changes and modifications may be made without departing from this exemplary embodiment(s) of the present invention and its broader aspects. Therefore, the appended claims are intended to encompass within their scope all such changes and modifications as are within the true spirit and scope of this exemplary embodiment(s) of the present invention.

What is claimed is:

1. A device, comprising:
a first circuit capable of generating an edge trigger signal in response to a waveform of an input signal and a waveform of an output signal;
a second circuit coupled to the first circuit and configure to facilitate removing a narrow pulse from the waveform of the input signal; and
a third circuit coupled to the first circuit and configured to generate a delayed output waveform having pulses greater than a predefined minimal pulse width.

2. The device of claim 1, wherein a first circuit is configured to perform an exclusive OR (“XOR”) function, which provides logic “1” when logic values of its two inputs are different.

3. The device of claim 2, wherein the second circuit includes a delay element capable of delaying a waveform of a signal for a predetermined time.

4. The device of claim 3, wherein the third circuit includes a D flip-flop triggered by a rising edge of the edge trigger signal and capable of filtering glitches from the waveform of the input signal.

5. The device of claim 4, wherein the third circuit further includes an inverter coupled between the D flip-flop and the delay element, and configured to generate an inverted waveform of the D input signal.

6. The device of claim 5, wherein the delay element provides a delay time, which is greater than predefined minimum allowed pulse width and less than half of a period of the input signal.

7. The device of claim 5, wherein the delay element provides a delay time, which equals to predefined minimum allowed pulse width and less than half of a period of the input signal.

8. The device of claim 1,
wherein the input signal is a clock signal; and
wherein the output signal is a regenerated version of input clock signal with glitches removed.

9. The device of claim 4, wherein the third circuit further includes an inverter coupled between a data input of the D flip-flop and a data output of the D flip-flop, and configured to generate an inverted waveform of the D input signal.

10. A method for removing narrow pulses comprising:
generating a delayed output waveform via delay logic for a predetermined period of time;
providing an edge trigger signal in response to an input signal and an output signal;
filtering a narrow pulse from the input signal in response to the delayed output waveform; and
generating the output signal in response to the input signal and the delayed output waveform, wherein generating the output signal further includes providing a delayed output signal with a narrow pulse removed.

11. The method of claim 10, wherein generating a delayed output waveform via delay logic further includes identifying a delay time that is greater than a predefined minimum allowed pulse width and less than half of a period of the input signal.

12. The method of claim 10, wherein generating a delayed output waveform via delay logic further includes identifying a delay time that equals to a predefined minimum allowed pulse width and less than half of a period of the input signal.

13. The method of claim 10, wherein providing an edge trigger signal includes feeding the input signal and the output signal to an exclusive OR gate to produce the edge trigger signal.

14. The method of claim 10, wherein filtering a narrow pulse from the input signal includes removing glitches from a waveform of the input signal utilizing a plurality of D flip-flops.

15. The method of claim 10, wherein generating the output signal in response to the input signal and delayed output waveform includes providing the output signal via a D flip-flop configured to receive the edge trigger signal for activating the D flip-flop.

16. The method of claim 10, wherein generating the output signal in response to the input signal and delayed output waveform includes providing the output signal via a D flip-flop configured to receive an inverted and delayed output waveform as data input.

17. An apparatus for removing narrow pulses comprising:
means for generating a delayed output waveform via delay logic for a predetermined period of time;
means for providing an edge trigger signal in response to an input signal and an output signal;
means for filtering a narrow pulse from the input signal in response to the delayed output waveform; and
means for generating the output signal in response to the input signal and the delayed output waveform, wherein mean for generating the output signal further includes providing a delayed output signal with a narrow pulse removed.

18. The apparatus of claim 17, wherein means for generating a delayed output waveform via delay logic further includes means for identifying a delay time that is greater than a predefined minimum allowed pulse width and less than half of a period of the input signal.

19. The apparatus of claim 17, wherein means for generating a delayed output waveform via delay logic further includes means for identifying a delay time that equals to a predefined minimum allowed pulse width and less than half of a period of the input signal.

20. The apparatus of claim 17, wherein means for providing an edge trigger signal includes means for feeding the input signal and the output signal to an exclusive OR gate to produce the edge trigger signal.
